(19) United States
(12) Patent Application Publication
(10) Pub. No.: US 2008/0296597 A1
(43) Pub. Date: Dec. 4, 2008

(54) Chip scale light emitting device

(76) Inventor: Pai-Chen Chieh, Taipei (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/984,342

(22) Filed: Nov. 16, 2007

(30) Foreign Application Priority Data
Jun. 1, 2007 (TW) 096119720

(51) Int. Cl. H01L 33/00

(52) U.S. Cl. 257/98; 257/E33.058

(57) ABSTRACT

A light emitting device includes: a circuit board having a dielectric substrate and first and second electrodes provided on the dielectric substrate, the dielectric substrate being formed with a retaining hole; and a light emitting diode chip received in the retaining hole in the dielectric substrate and connected electrically to the first and second electrodes.

### CROSS-REFERENCE TO RELATED APPLICATION

This application claims priority of Taiwanese Application No. 096119720, filed on Jun. 1, 2007.

### BACKGROUND OF THE INVENTION

1. Field of the Invention

The invention relates to a light emitting device, more particularly to a chip scale light emitting device including a circuit board and a light emitting diode chip disposed in a retaining hole in the circuit board.

2. Description of the Related Art

The fashion trend of the cell phone industry in the past years has focused on extremely thin cell phones. As such, the light emitting devices mounted underneath a keypad of the cell phone for illuminating purpose are required to have a height or a thickness as small as possible (in the order of micro scale) so as to be fitted into the cell phone. Since the light emitting devices are disposed underneath the keypad, they can be felt by touching the keypad when the height of the light emitting devices is relatively large, which can cause an uncomfortable feeling like touching a protrusion.

FIG. 1 illustrates a conventional light emitting device that includes a circuit board 11 with a thickness of about 0.1 mm, a light emitting diode (LED) chip 12 stacked on the circuit board 11 and having a height of about 0.1 mm, and a transparent enclosure 13 enclosing the LED chip 12. Conventionally, the height of the light emitting device can only be reduced to about 0.35 mm. In addition, the heat generated from the LED chip 12 is dissipated mainly through a pair of conductive wires 14, which are connected to the LED chip 12 and electrodes 111 formed on the circuit board 11, which is relatively inefficient. Particularly, the problem of inefficient heat dissipation can reduce the service life of the LED chip when the LED chip is a high power and high luminance LED chip.

### SUMMARY OF THE INVENTION

Therefore, the object of the present invention is to provide a light emitting device that can overcome the aforesaid drawbacks associated with the prior art.

According to one aspect of this invention, there is provided a light emitting device that comprises: a circuit board having a dielectric substrate and first and second electrodes provided on the dielectric substrate, the dielectric substrate being formed with a retaining hole; and a light emitting diode chip received in the retaining hole in the dielectric substrate and connected electrically to the first and second electrodes.

According to another aspect of this invention, there is provided a chip-scale light emitting device that comprises an assembly of a circuit board, a light emitting diode chip, and a transparent enclosure. The circuit board has a dielectric substrate, and first and second electrodes provided on the dielectric substrate. The light emitting diode chip is electrically connected to the first and second electrodes. The transparent enclosure is formed on the circuit board and covers the light emitting diode chip. The light emitting diode chip has a height on the same order of thickness of the dielectric substrate. The assembly of the circuit board, the light emitting diode chip and the transparent enclosure has a thickness of less than 0.35 mm. The dielectric substrate of the circuit board is formed with a retaining hole that receives the light emitting diode chip therein.

### BRIEF DESCRIPTION OF THE DRAWINGS

Other features and advantages of the present invention will become apparent in the following detailed description of the preferred embodiments with reference to the accompanying drawings, of which:

FIG. 1 is a schematic partly sectional view of a conventional light emitting device;

FIG. 2 is a schematic partly sectional view of the first preferred embodiment of a light emitting device according to the present invention;

FIG. 3 is a schematic partly sectional view of the second preferred embodiment of the light emitting device according to this invention; and

FIG. 4 is a schematic partly sectional view of the third preferred embodiment of the light emitting device according to this invention.

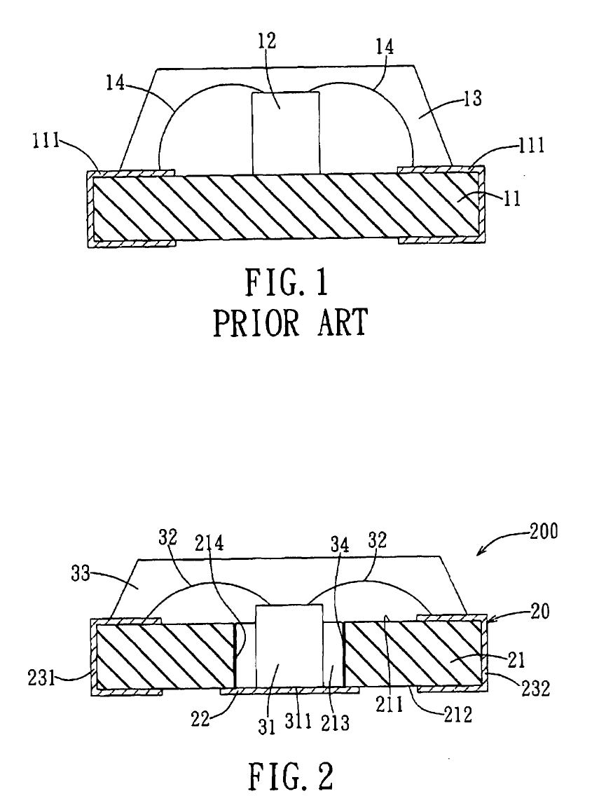

### DETAILED DESCRIPTION OF THE PREFERRED EMBODIMENTS

Before the present invention is described in greater detail with reference to the accompanying preferred embodiments, it should be noted herein that like elements are denoted by the same reference numerals throughout the disclosure.

FIG. 2 illustrates the first preferred embodiment of a chip-scale light emitting device 200 according to the present invention. The chip scale light emitting device 200 includes an assembly of a circuit board 20, a light emitting diode chip 31, and a transparent enclosure 33. The circuit board 20 has a dielectric substrate 21, and first and second electrodes 231, 232 provided on the dielectric substrate 21. The light emitting diode chip 31 is electrically connected to the first and second electrodes 231, 232 through a pair of conductive wires 32. The transparent enclosure 33 is formed on the circuit board 20 and covers the conductive wires 32 and the light emitting diode chip 31. The light emitting diode chip 31 has a height on the same order of thickness of the dielectric substrate 2. The assembly of the circuit board 20, the light emitting diode chip 31 and the transparent enclosure 33 has a thickness of less than 0.35 mm. The dielectric substrate 21 of the circuit board 20 is formed with a retaining hole 213 that receives the light emitting diode chip 31 therein.

The dielectric substrate 21 has first and second surfaces 211, 212. The retaining hole 213 extends through the first and second surfaces 211, 212 of the dielectric substrate 21. The first and second electrodes 231, 232 are formed on the first and second surfaces 211, 212 of the dielectric substrate 21. The second surface 212 of the dielectric substrate 21 is provided with a heat dissipating member 22 having a portion that is exposed from the retaining hole 213 and that is in contact with the light emitting diode chip 31.

In this embodiment, the heat dissipating member 22 is in the form of a conductive foil attached to the second surface 212 of the dielectric substrate 21. The light emitting diode chip 31 has a flat bottom 311 that is in face-to-face contact with the heat dissipating member 22. The retaining hole 213 in the dielectric substrate 21 is cylindrical in shape, and has an open end at the second surface 212 of the dielectric substrate 21. The heat dissipating member 22 covers the open end of the retaining hole 213.

The retaining hole 213 in the dielectric substrate 21 is defined by a hole-defining wall 214 that is provided with a reflective member 34 which is preferably made from a deposited metal film using vapor deposition techniques or sputtering techniques so as to enhance light extraction efficiency of the chip scale light emitting device 200. Alternatively, the dielectric substrate 21 can be made from a white material so that the hole-defining wall 214 of the retaining hole 213 can also exhibit a light reflective property.

The illuminating intensity and direction of the chip scale light emitting device 200 can be adjusted by varying the shape of the retaining hole 213 in the dielectric substrate 21.

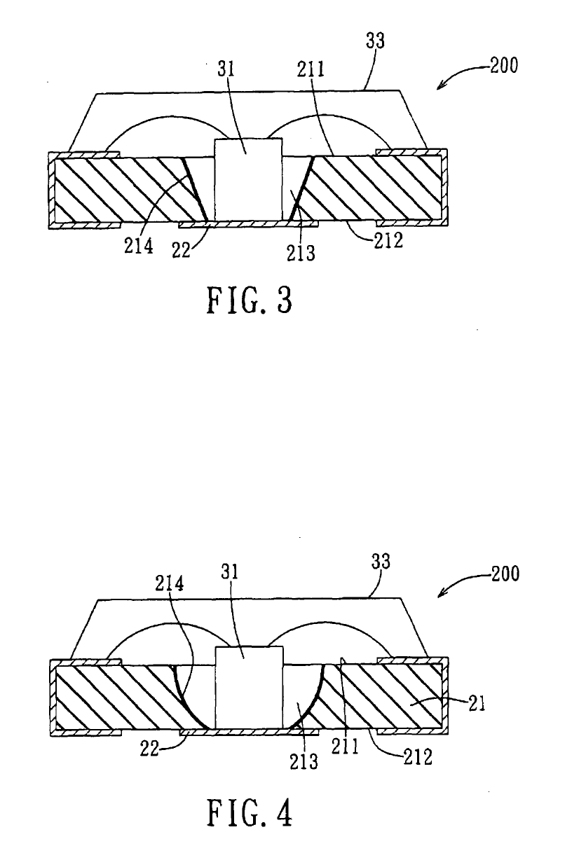

FIG. 3 illustrates the second preferred embodiment of the chip scale light emitting device 200 according to this invention. The second preferred embodiment differs from the previous embodiment in that the retaining hole 213 in the dielectric substrate 21 is frusto-conical in shape and is tapered in a direction from the first surface 211 to the second surface 212 of the dielectric substrate 21.

FIG. 4 illustrates the third preferred embodiment of the chip scale light emitting device 200 according to this invention. The third preferred embodiment differs from the previous embodiments in that the hole-defining wall 214 of the retaining hole 213 is curved (bowl shape) and is gradually reduced in cross-section in a direction from the first surface 211 to the second surface 212 of the dielectric substrate 21.

By forming the retaining hole 213 in the dielectric substrate 21 of the circuit board 20 of the chip scale light emitting device 200 of this invention, the light emitting diode chip 31 can be mounted therein, thereby permitting a reduction in the height of the chip scale light emitting device 200 to about 0.2 mm. Moreover, formation of the retaining hole 213 also permits direct attachment of the heat dissipating member 22 to the bottom of the light emitting diode chip 31, thereby greatly enhancing heat dissipating efficiency of the chip scale light emitting device 200.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A light emitting device comprising:
a circuit board having a dielectric substrate and first and second electrodes provided on said dielectric substrate, said dielectric substrate being formed with a retaining hole; and
a light emitting diode chip received in said retaining hole in said dielectric substrate and connected electrically to said first and second electrodes.

2. The light emitting device of claim 1, wherein said dielectric substrate has first and second surfaces, said retaining hole extending through said first and second surfaces of said dielectric substrate, said first and second electrodes being formed on said first and second surfaces of said dielectric substrate, said second surface of said dielectric substrate being provided with a heat dissipating member having a portion that is exposed from said retaining hole and that is in contact with said light emitting diode chip.

3. The light emitting device of claim 2, wherein said heat dissipating member is in the form of a conductive foil attached to said second surface of said dielectric substrate, said light emitting diode chip having a flat bottom that is in face-to-face contact with said heat dissipating member.

4. The light emitting device of claim 2, wherein said retaining hole in said dielectric substrate has an open end at said second surface of said dielectric substrate, said heat dissipating member covering said open end of said retaining hole.

5. The light emitting device of claim 2, wherein said dielectric substrate exhibits a light reflective property.

6. The light emitting device of claim 5, wherein said retaining hole is frusto-conical in shape and is tapered in a direction from said first surface to said second surface of said dielectric substrate.

7. The light emitting device of claim 5, wherein said retaining hole is defined by a curved hole-defining wall that is gradually reduced in cross-section in a direction from said first surface to said second surface of said dielectric substrate.

8. The light emitting device of claim 1, wherein said retaining hole is defined by a hole-defining wall that is provided with a reflective member.

9. The light emitting device of claim 1, wherein said reflective member is made from a deposited metal film.

10. The light emitting device of claim 2, further comprising a pair of conductive wires, each of which is connected to said light emitting diode chip and a respective one of said first and second electrodes.

11. The light emitting device of claim 10, further comprising a transparent enclosure formed on said circuit board and covering said conductive wires and said light emitting diode chip.

12. A chip-scale light emitting device comprising an assembly of a circuit board, a light emitting diode chip, and a transparent enclosure, said circuit board having a dielectric substrate, and first and second electrodes provided on said dielectric substrate, said light emitting diode chip being electrically connected to said first and second electrodes, said transparent enclosure being formed on said circuit board and covering said light emitting diode chip, said light emitting diode chip having a height on the same order of thickness of said dielectric substrate, the assembly of said circuit board, said light emitting diode chip, and said transparent enclosure having a thickness of less than 0.35 mm,
wherein said dielectric substrate of said circuit board is formed with a retaining hole that receives said light emitting diode chip therein.

13. The chip-scale light emitting device of claim 12, further comprising a heat dissipating member that is attached to said dielectric substrate and that has a portion exposed from said retaining hole and in contact with said light emitting diode chip.

14. The chip-scale light emitting device of claim 12, wherein said retaining hole in said dielectric substrate is defined by a hole-defining wall which is provided with a reflective member.
